(19) United States
(12) Patent Application Publication
(10) Pub. No.: US 2014/0091472 A1
(43) Pub. Date: Apr. 3, 2014

(54) SEMICONDUCTOR DEVICE AND MANUFACTURING METHOD OF THE SAME

(71) Applicant: KABUSHIKI KAISHA TOSHIBA, Tokyo (JP)

(72) Inventors: Kyoko HONMA, Kanagawa (JP); Kazuo SHIMOKAWA, Kanagawa (JP)

(73) Assignee: KABUSHIKI KAISHA TOSHIBA, Tokyo (JP)

(21) Appl. No.: 14/016,174

(22) Filed: Sep. 2, 2013

(30) Foreign Application Priority Data
Oct. 1, 2012 (JP) 2012-219729

(51) Int. Cl. H01L 23/48; H01L 21/78

(52) U.S. Cl. CPC H01L 23/48; H01L 21/78
USPC 257/773; 438/113

(57) ABSTRACT

A semiconductor element includes a plurality of electrodes on a main surface, a sealing resin covering at least a part of a side surface of the semiconductor element, and a first insulating layer formed on the main surface of the semiconductor element, a part of the side surface of the semiconductor element, and the sealing resin. The first insulating layer has first openings formed therein to allow the plural electrodes on the main surface to be exposed through the first openings, and a fillet provided on a part of the side surface. The semiconductor element further includes a wiring layer formed in the first openings in such a manner as to be electrically connected to the plural electrodes, and also formed on the first insulating layer, and a second insulating layer having second openings formed on the first insulating layer and the wiring layer.

### CROSS-REFERENCE TO RELATED APPLICATION

This application is based upon and claims the benefit of priority from Japanese Patent Application No. 2012-219729, filed Oct. 1, 2012, the entire contents of which are incorporated herein by reference.

### FIELD

Embodiments described herein relate to a semiconductor device and a manufacturing method of this semiconductor device.

### BACKGROUND

Recently, products such as cellular phones and digital media players are being downsized. With the miniaturization of these products, the demand for downsized semiconductor devices installed in such products is also rising. Recently, compact semiconductor devices including a small semiconductor device called a Chip Size Package (CSP), which contains a semiconductor element sealed by resin, have been developed.

However, providing compact semiconductor devices on the products is difficult due to the limitation of fine wiring technologies used for positioning electrode pads and wires on a substrate where a semiconductor device is mounted. To overcome this problem, semiconductor devices having fan-out structure where electrodes of the semiconductor element are re-wired to increase the electrode pitch are in demand.

According to a manufacturing method for a semiconductor device having fan-out structure in the related art, semiconductor elements are initially mounted on a support member provided with a fixing member, and the semiconductor elements are sealed by resin. After the support member is separated, an insulating layer is formed on the semiconductor elements and the sealing resin. Then, a wiring layer and a solder resist layer are formed, and finally the semiconductor elements are separated from one another into discrete pieces.

### BRIEF DESCRIPTION OF THE DRAWINGS

FIG. 1 is a cross-sectional view of a semiconductor device according to an embodiment.

FIGS. 2A through 2E are cross-sectional views schematically illustrating steps of a manufacturing method of the semiconductor device according to the embodiment.

FIGS. 3A through 3C are cross-sectional views schematically illustrating additional steps of the manufacturing method of the semiconductor device according to the embodiment.

FIGS. 4A and 4B are cross-sectional views schematically illustrating additional steps of the manufacturing method of the semiconductor device according to the embodiment.

FIG. 5 is a cross-sectional view of a first modified example of the semiconductor device according to the embodiment.

FIG. 6 is a cross-sectional view of a second modified example of the semiconductor device according to the embodiment.

FIG. 7 is a cross-sectional view of a third modified example of the semiconductor device according to the embodiment.

### DETAILED DESCRIPTION

During the process for forming a wiring layer or the process for heat treating a solder resist layer, stress is generated between an insulating layer and two components of a semiconductor element and a sealing resin as a result of warping or a difference in the thermal expansion coefficients. According to the related-art semiconductor device, the surfaces of the semiconductor element and the sealing resin are substantially uniform, and consequently, the adhesion between the insulating layer and the two components of the semiconductor element and the sealing resin becomes insufficient to possibly cause a separation of the insulating layer. In such a case, the semiconductor device does not provide sufficient reliability.

Accordingly, an object achieved by an embodiment is to provide a semiconductor device having higher reliability.

For achieving the above object, a semiconductor device according to one embodiment includes: a semiconductor element having a plurality of electrodes on a main surface; a sealing resin covering at least a part of a side surface of the semiconductor element; a first insulating layer formed on the main surface of the semiconductor element, a part of the side surface of the semiconductor element, and the sealing resin, and having first openings provided in such a manner as to allow the plural electrodes on the main surface to be exposed through the first openings, and a fillet provided on a part of the side surface; a wiring layer formed in the first openings in such a manner as to be electrically connected to the plural electrodes, and also formed on the first insulating layer; and a second insulating layer having second openings formed on the first insulating layer and the wiring layer.

A semiconductor device manufacturing method according to one embodiment includes: positioning semiconductor elements on a first insulating layer which is fixed to a support member by a fixing member formed on the support member, the first insulating layer being patterned to have first openings, to produce fillets on side surfaces of the semiconductor elements; forming sealing resin on at least the first insulating layer and the semiconductor elements; separating the fixing member from the support member to expose the first openings; forming the wiring layer in the first openings and on the first insulating layer; forming a second insulating layer having second openings on at least the first insulating layer and the wiring layer; and separating the semiconductor elements from one another to produce discrete semiconductor elements.

An embodiment is hereinafter described with reference to the drawings. Similar elements are given similar reference numbers in the respective drawings, and the same detailed description is not repeated.

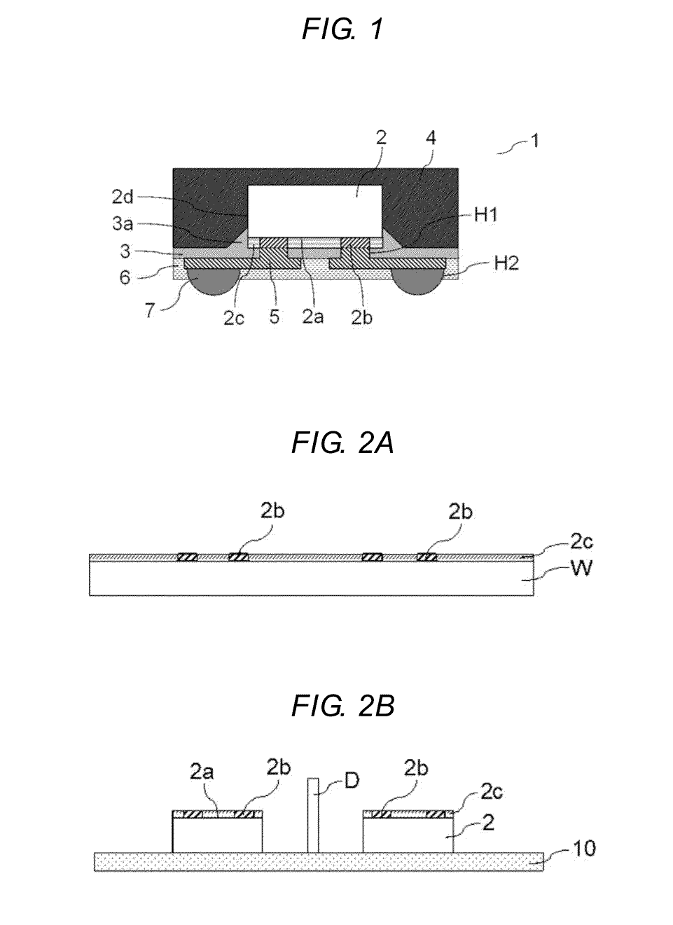

FIG. 1 is a cross-sectional view of a semiconductor device according to this embodiment. A semiconductor device 1 in this embodiment includes a semiconductor element 2, an insulating layer 3, a sealing resin 4, a wiring layer 5, a solder resist 6, and connection members 7.

The semiconductor element 2 has a plurality of electrodes 2b on a main surface 2a, and an insulating member 2c provided on the main surface 2a in such a manner as to surround the plural electrodes 2b. The insulating member 2c prevents continuity across the adjacent electrodes 2b when the plural electrodes 2b are energized. The insulating member 2c provided in such a manner as to surround the plural electrodes 2b in this embodiment may cover a part of the plural electrodes 2b and surround the electrodes 2b while allowing exposure of the plural electrodes 2b.

The semiconductor element 2 is quadrangle-pole-shaped, and constituted by a logic-type LSI element, a discrete semiconductor such as a diode, a memory element or other elements. The semiconductor element which is quadrangle-pole-shaped in this embodiment may have other shapes such as a polygon pole shape and a cylindrical shape.

The insulating layer 3 (first insulating layer) has a fillet 3a which covers a part of a side surface 2d of the semiconductor element 2. The side surface 2d crosses the main surface 2a substantially at right angles. The fillet 3a is formed by the insulating layer 3 rising up along a part of the side surface 2d. The fillet 3a covers the insulating member 2c and a part of the side surface 2d.

The insulating layer 3 provided at least on the insulating member 2c of the semiconductor element 2 forms first openings H1 to allow exposure of the plural electrodes 2b through the first openings H1. More specifically, the first openings H1 of the insulating layer 3 are so formed as to allow electrical connection of the wiring layer 5 described below. The insulating layer 3 surrounding the plural electrodes 2b according to this embodiment may contact a part of the plural electrodes 2b, for example, as long as the plural electrodes 2b can be exposed through the insulating layer 3.

The insulating layer 3 provided on the insulating member 2c and the fillet 3a are continuously formed.

The structure which has the insulating layer 3 covering a part of the side surface 2d of the semiconductor element 2 can increase the adhesive area between the insulating layer 3 and the components of the semiconductor element 2 and the sealing resin 4, thereby increasing the adhesion between the insulating layer 3 and the components 2 and 4. Accordingly, this structure can prevent separation of the insulating layer 3.

The insulating layer 3 made of material including polyimide in this embodiment may be made of other materials as long as the materials can insulate the plural electrodes 2b from one another.

The sealing resin 4 is provided on the surface of the semiconductor element 2 on the side opposed to the main surface 2a, a part of the side surface 2d, and the insulating layer 3. The material of the sealing resin 4 may be epoxy resin, for example, but is not limited to this material.

The wiring layer 5 is electrically connected to the plural electrodes 2b of the semiconductor element 2, and fills in the first openings H1 of the insulating layer 3. The wiring layer 5 is formed on the insulating layer 3 on the side opposed to the side where the sealing resin 4 is provided, and has a substantially uniform thickness. The wiring layer 5 is made of conductive metal such as Cu and Al, for example.

The solder resist 6 (second insulating layer) is provided on the insulating layer 3 and the wiring layer 5 and positioned so as to surround the area of the connection members 7 provided on the wiring layer 5. The material of the solder resist 6 is a material containing polyimide, but is not limited to this material.

The connection members 7 are provided in second openings H2 of the solder resist 6 and is electrically connected to the wiring layer 5. Each of the connection members 7 is constituted by a soldering ball in this embodiment, but may be formed by other materials as long as a conductive metal is included.

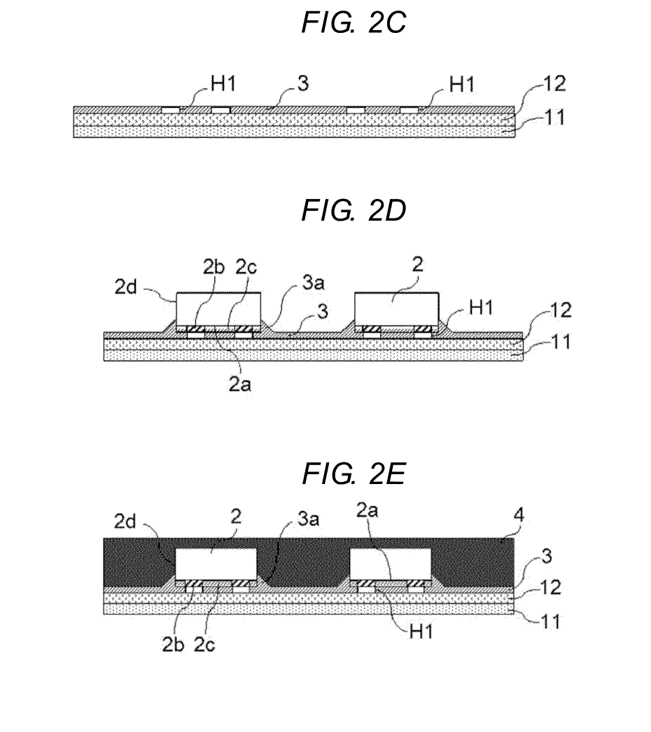

A manufacturing method of a semiconductor device according to this embodiment is now explained with reference to FIGS. 2A through 4B.

Initially, a wafer W which includes the plural electrodes 2b and the insulating member 2c surrounding the plural electrodes 2b in such a manner as to allow exposure of the electrodes 2b through the insulating member 2c is prepared as illustrated in FIG. 2A. As illustrated in FIG. 2B, the wafer W is positioned on a first support member 10, and cut into discrete pieces by using a dicing blade D to produce the semiconductor elements 2. The first support member 10 is constituted by a sheet, such as a dicing tape, in this embodiment. However, the first support member 10 may be formed by other materials as long as the materials can be diced.

As illustrated in FIG. 2C, a fixing member 12 having adhesion is formed on a second support member 11, and the insulating layer 3 is further provided on the fixing member 12. The insulating layer 3 is produced by patterning such that the first openings H1 can be formed at positions coinciding with the positions of the electrodes 2b of the semiconductor elements 2.

The insulating layer 3 may be produced by printing with desired patterns. For example, the insulating layer 3 may be formed by lithography patterning using photosensitive resin such as polyimide.

The insulating layer 3 is so formed as to rise up along the side surfaces 2d of the semiconductor elements 2 at the time of mounting of the semiconductor elements 2. It is therefore preferable that the insulating layer 3 is hardened not completely but only partially when formed. The condition of the insulating layer 3 is not limited to the partially hardened condition but may be any conditions as long as the insulating layer 3 can rise up with sufficient fluidity.

The second support member 11 may be made of any materials such as glass, metal and Si. It is preferable, however, that the second support member 11 is made of material which has sufficient thickness and rigidity for preventing warping or the like produced when the semiconductor elements 2 is mounted and the sealing resin 4 is formed in subsequent steps.

The fixing member 12 is made of material whose adhesion level decreases by heat treatment or exposure treatment, for example, so that the fixing member 12 and the second support member 11 can be separated in a subsequent step. According to this embodiment, the fixing member 12 is constituted by an adhesive double coated sheet. However, the material of the fixing member 12 is not limited to this example but may be an adhesive or wax, for example.

As illustrated in FIG. 2D, the semiconductor elements 2 are mounted on the insulating layer 3. In this step, the semiconductor elements 2 are mounted while aligning the electrodes 2b of the semiconductor elements 2 with the first openings H1 of the insulating layer 3 using a mounting device, for example. The mounting step performed by using the mounting device in this embodiment may be carried out by other methods.

The semiconductor elements 2 may be mounted while using the openings H1 as positioning marks. When patterns other than the first openings H1 are formed, the semiconductor elements 2 may be mounted while using those patterns as positioning marks. These methods can increase the accuracy of positioning when mounting the semiconductor elements 2. With the increased accuracy, the positional deviation in the following steps decreases. As a result, the semiconductor device 1 thus manufactured can obtain high accuracy and high reliability.

The mounting of the semiconductor elements 2 causes the insulating layer 3 to rise up along the side surfaces 2d of the semiconductor elements 2 and form the fillets 3a.

The semiconductor devices to be mounted are arranged at predetermined intervals in accordance with the size of the semiconductor devices finally produced. For example, when a package having a length of 2 mm and including the 1 mm-long semiconductor element 2 is to be manufactured, the semiconductor elements 2 are mounted at intervals of 2 mm.

As illustrated in FIG. 2E, the sealing resin 4 is formed on the semiconductor elements 2 and the insulating layer 3 to provide resin sealing, and the sealing resin 4 is hardened by heating. The sealing resin 4 is formed by molding such as printing and compression molding.

When the semiconductor elements 2 are positioned on the fixing member 12 only via the insulating layer 3, a shearing stress is applied to the semiconductor elements 2 by resin flow at the time of forming the sealing resin 4. In this case, positional deviation and separation of the semiconductor elements 2 may occur. Therefore, the forming of the sealing resin 4 is required to be carried out in appropriate conditions (such as appropriate applied pressure and speed). According to this embodiment, however, the fillets 3a of the insulating layer 3 provided on the side surfaces 2d of the semiconductor elements 2 increase the adhesion and produce a firmly fixed condition, preventing positional deviation and separation. Accordingly, the product thus manufactured obtains high positional accuracy and high reliability. Furthermore, the range of the appropriate manufacturing conditions can be widened, and thus, the product can be more easily manufactured.

When the sealing resin 4 is hardened by heating, the insulating layer 3 in the partially hardened condition can be simultaneously hardened by heating. The insulating layer 3 may be hardened by heating before the sealing resin 4 is formed.

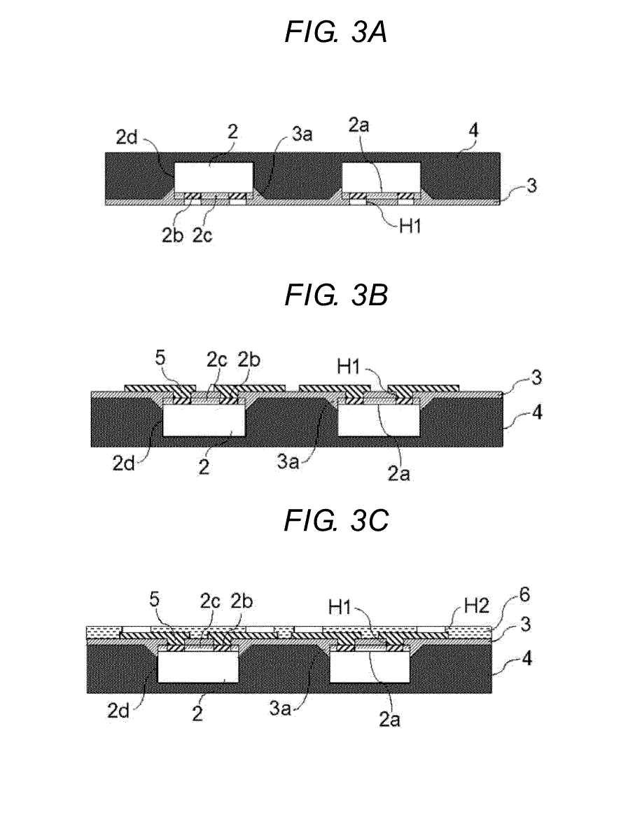

As illustrated in FIG. 3A, the second support member 11 and the fixing member 12 are separated. The two components 11 and 12 are separated by an appropriate method such as heating or exposure in accordance with the material of the fixing member 12 to be used.

As illustrated in FIG. 3B, the wiring layer 5 is formed in the first openings H1 and on the insulating layer 3. The wiring layer 5 is formed by plating, for example.

As illustrated in FIG. 3C, the solder resist 6 is formed on the insulating layer 3 and the wiring layer 5, and hardened thereon by heating. The solder resist 6 is provided with the second openings H2 formed in such a manner as to surround the areas of the connection members 7 to be positioned. The solder resist 6 may be formed by printing, for example. The second openings H2 may be produced using masks, or by lithography, for example.

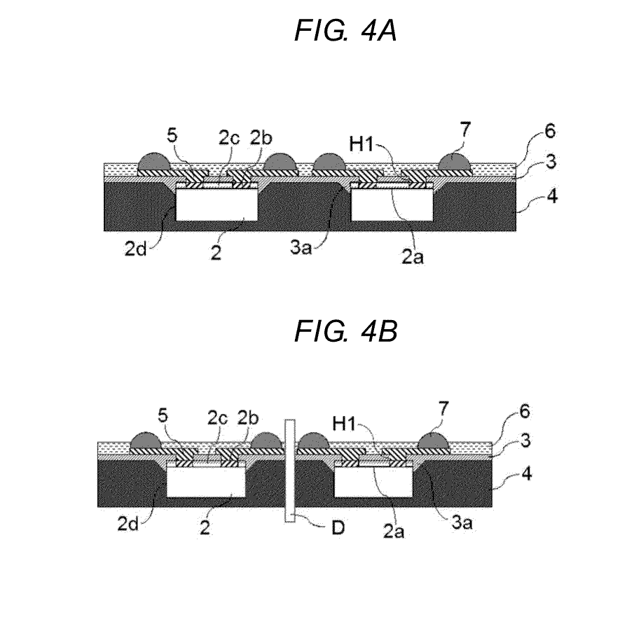

As illustrated in FIG. 4A, the connection members 7 are positioned in the second openings H2. According to this embodiment, the connection members 7 are constituted by soldering balls. However, the connection members 7 may be other metal balls made of conductive metal. The connection members 7 may have shapes other than the ball shape as long as the semiconductor device 1 can be positioned on a substrate via the connection members 7.

Finally, as illustrated in FIG. 4B, the semiconductor elements 2 are separated into discrete pieces by using the dicing blade D to produce the semiconductor device 1.

According to this embodiment described herein, the fillets 3a of the insulating layer 3 rise up along the side surface 2d of the semiconductor element 2. This structure can prevent positional deviation and separation. Accordingly, the product thus manufactured can obtain high positional accuracy and high reliability.

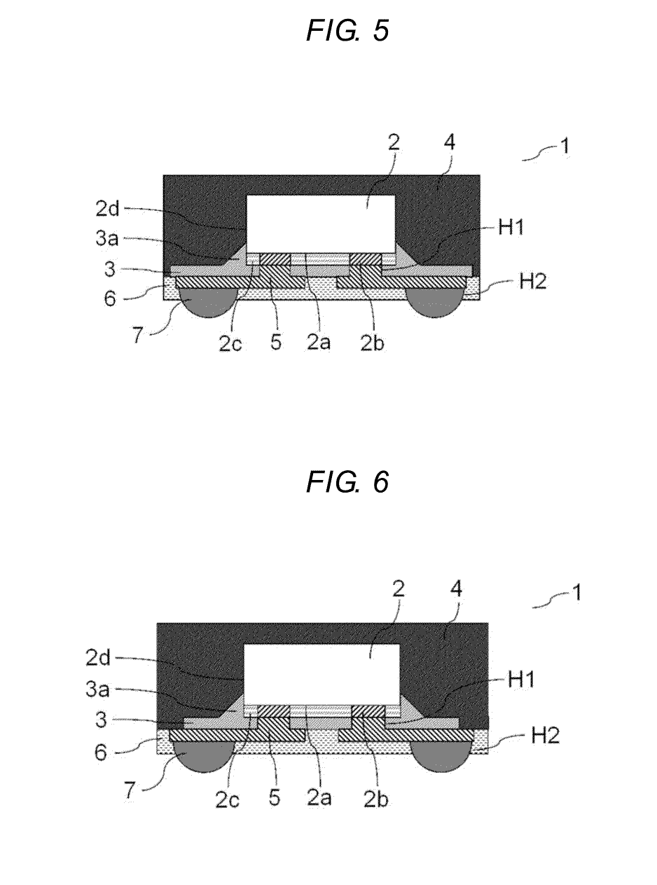

According to this embodiment, the insulating layer 3 is disposed in such a manner as to separate the sealing resin 4 from the solder resist 6. However, this structure can be modified in the following manner, for example. As illustrated in FIG. 5, the pattern shape of the insulating layer 3 may be covered by the solder resist 6, producing contact between the sealing resin 4 and the solder resist 6. In this case, the interface between the insulating layer 3 and the sealing resin 4 is not exposed to the outside, wherefore separation can be further securely avoided.

According to this embodiment, the area of the insulating layer 3 is larger than the pattern area of the wiring layer 5. However, this structure can be modified in the following manner, for example. As illustrated in FIG. 6, the wiring layer may cover a part of the insulating layer 3 and contact the sealing resin 4. In this case, the wiring layer 5 can closely contact the sealing resin 4, wherefore separation of the insulating layer 3 can be further securely avoided.

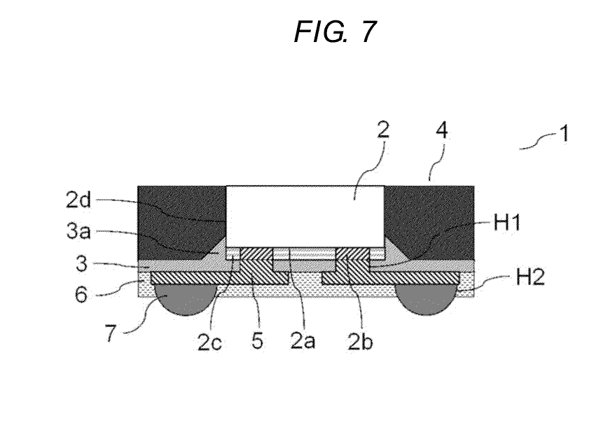

According to this embodiment, the surface of the semiconductor element 2 on the side opposite to the main surface 2a is covered by the sealing resin 4. However, this structure may be modified in the following manner, for example. As illustrated in FIG. 7, the surface of the semiconductor element 2 on the side opposite to the main surface 2a may be exposed. In this case, the corresponding surface can be exposed by removing part of the sealing resin 4 using BSG (back side grind) after the sealing resin 4 is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor element including a plurality of electrodes on a main surface;
a sealing resin covering at least a part of a side surface of the semiconductor element;
a first insulating layer formed on the main surface of the semiconductor element, a part of the side surface of the semiconductor element, and the sealing resin, and provided with first openings in such a manner as to allow the plural electrodes on the main surface to be exposed through the first openings, and including a fillet provided on a part of the side surface;
a wiring layer formed in the first openings in such a manner as to be electrically connected to the plurality of electrodes, and also formed on the first insulating layer; and
a second insulating layer provided with second openings formed on at least the first insulating layer and the wiring layer.

2. The device according to claim 1, wherein the second insulating layer covers the first insulating layer and contacts the sealing resin.

3. The device according to claim 2, wherein the wiring layer covers a part of the first insulating layer and contacts the sealing resin.

4. The device according to claim 1, wherein the wiring layer covers a part of the first insulating layer and contacts the sealing resin.

5. The device according to claim 1, wherein the sealing resin also covers a surface of the semiconductor element that is opposite the main surface.

6. A semiconductor device manufacturing method, comprising:
positioning semiconductor elements on a fixing member formed on the support member, the first insulating layer being patterned to have first openings, to produce fillets on side surfaces of the semiconductor elements;
forming sealing resin on at least the first insulating layer and the side surfaces of the semiconductor elements;
peeling off the fixing member and the support member to expose the first openings;
forming the wiring layer in the first openings and on the first insulating layer;
forming a second insulating layer having second openings on at least the first insulating layer and the wiring layer; and
separating the semiconductor elements to be discrete from one another.

7. The method according to claim 6, wherein the first insulating layer is fluid during said positioning of the semiconductor elements on the first insulating layer.

8. The method according to claim 7, wherein during said positioning, the pattern of the first insulating layer is used to align the semiconductor elements on the first insulating layer.

9. The method according to claim 6, wherein during said positioning, the pattern of the first insulating layer is used to align the semiconductor elements on the first insulating layer.

10. The method according to claim 6, wherein the second insulating layer is formed to cover the first insulating layer.

11. The method according to claim 6, wherein the wiring layer is formed to cover a part of the first insulating layer, and is also formed on the sealing resin.

12. The method according to claim 6, further comprising:
grinding to remove the sealing resin from and expose top surfaces of the semiconductor elements.
